(19) United States
(12) Patent Application Publication
(10) Pub. No.: US 2026/0171743 A1
(43) Pub. Date: Jun. 18, 2026

(54) ELECTRONIC COMPONENT DETACHING TOOL

(71) Applicant: FURUKAWA ELECTRIC CO., LTD., Tokyo (JP)

(72) Inventors: Yasuhiro UCHIMURA, Tokyo (JP); Hiroshi KATO, Tokyo (JP); Hirofumi AOKI, Tokyo (JP)

(73) Assignee: FURUKAWA ELECTRIC CO., LTD., Tokyo (JP)

(21) Appl. No.: 19/530,559

(22) Filed: Feb. 5, 2026

Related U.S. Application Data
(63) Continuation of application No. PCT/JP2025/031054, filed on Sep. 3, 2025.

(30) Foreign Application Priority Data
Sep. 5, 2024 (JP) 2024-153284

(51) Int. Cl. H01R 43/26; H01R 12/73; H01R 13/627; H01R 13/633; H01R 13/635; H01R 25/00

(52) U.S. Cl. CPC H01R 43/26; H01R 12/737; H01R 13/6275; H01R 13/6335; H01R 13/635; H01R 25/006

(57) ABSTRACT

An electronic component detaching tool is provided that allows for easily detaching of a plate-shaped electronic component attached to a socket provided on a board from the socket. An electronic component detaching tool 100 for use in detaching a plate-shaped memory module 30 attached to a socket 20 provided on a board 10 includes: a detaching tool body 110; a pair of arms 120 provided to the detaching tool body 110 to respectively operate a pair of levers 22 in a state where the engaging portion 22a is engaged with the memory module 30 inserted in the groove 21a in a direction to disengage the engaging portions 22a from the memory module 30; and a retainer 140 provided to the detaching tool body 110 to retain the memory module 30 for which engagement of the engaging portions 22a has been released by the pair of arms 120.

### CROSS REFERENCE TO RELATED APPLICATIONS

This application claims the benefit of priority to Japanese Patent Application No. 2024-153284 filed on Sep. 5, 2024 and is a Continuation Application of PCT Application No. PCT/JP 2025/031054 filed on Sep. 3, 2025. The entire contents of each application are hereby incorporated herein by reference.

### BACKGROUND OF THE INVENTION

### 1. Field of the invention

The present invention relates to an electronic component detaching tool for use in detaching a plate-shaped electronic component attached to a socket on a board.

### 2. Description of the Related Art

For example, an attaching/detaching mechanism that has been known in the art enables attachment/detachment of a plate-shaped electronic component, such as a memory card, to/from a socket, such as a card slot, on a board (see, for example, Patent Document 1: Japanese Unexamined Patent Application, Publication No. 2001-086089). An attaching/detaching mechanism of Patent Document 1 inserts and pushes an electronic component into a socket to fix the electronic component to a predetermined portion of the socket, and pushes the electronic component attached to the socket toward the socket to release the fixed state of the electronic component to the socket, thereby detaching the electronic component from the socket.

In addition, for example, an integrated circuit (IC) remover that has been known in the art is used to remove an IC housed in an IC socket on a printed circuit board from the IC socket (see, for example, Patent Document 2: Japanese Unexamined Utility Model Application, Publication No. S58-95049). An IC remover of Patent Document 2 includes a pair of clip pieces between which an IC housed in an IC socket is sandwiched, and a slide lever for use to operate the pair of clip pieces. Operating the slide lever of the IC remover of Patent Document 2 above the IC housed in the IC socket allows the IC to be sandwiched between the pair of clip pieces, and allows the pair of clip pieces to be pulled upward to remove the IC from the IC socket.

Some sockets for use in connecting a memory module serving as a plate-shaped electronic component to an electronic circuit on a board include a socket body and a pair of levers. The socket body has a groove in which one end portion of the plate-shaped electronic component is inserted. The pair of levers each have an engaging portion that is engageable with the memory module inserted in the groove of the socket body. The pair of levers are moved from the outside toward the inside along an extending direction of the groove to engage the engaging portions with the memory module, and are moved from the inside toward the outside along the extending direction of the groove to disengage the engaging portions from the memory module.

In a case in which the memory module is to be detached from the socket to which the memory module has been attached, the pair of levers are moved outward along the extending direction of the groove to disengage the engaging portions from the memory module, and then the memory module is detached from the groove.

In other words, in the case in which the memory module is to be detached from the socket, an operation needs to be performed to detach the memory module from the socket after an operation has been performed to operate the pair of levers to disengage the engaging portions from the memory module. The task for detaching the memory module from the socket is complicated.

### SUMMARY OF THE INVENTION

An object of the present invention is to provide an electronic component detaching tool that enables easy detachment of a plate-shaped electronic component attached to a socket on a board from the socket.

An electronic component detaching tool according to the present invention is directed to an electronic component detaching tool for use in detaching a plate-shaped electronic component attached to a socket provided on a board. The socket includes a socket body having a groove in which one end portion of the electronic component is inserted, and a pair of levers respectively provided on both sides of the socket body in an extending direction of the groove, the pair of levers each having an engaging portion that is engageable with the electronic component inserted in the groove, the pair of levers being moved from outside toward inside along the extending direction of the groove to engage the engaging portions with the electronic component, the pair of levers being moved from inside toward outside along the extending direction of the groove to disengage the engaging portions from the electronic component. The electronic component detaching tool includes: a detaching tool body; a pair of arms provided to the detaching tool body to respectively operate the pair of levers in a state where the engaging portion is engaged with the electronic component inserted in the groove in a direction to disengage the engaging portions from the electronic component; and a retainer provided to the detaching tool body to retain the electronic component for which engagement of the engaging portions has been released by the pair of arms.

In the electronic component detaching tool according to the present invention, it is preferable for the pair of arms each to include an abutting portion configured to abut against one other member spaced apart upward from a corresponding one of the levers on the board, when the detaching tool body is moved toward the electronic component inserted in the groove of the socket body, and an action of operating the lever in a direction releasing engagement of the engaging portion from the electronic component is performed by the abutting portion abutting against the other member.

The electronic component detaching tool according to the present invention preferably further includes a posture retaining member configured to retain postures of the pair of arms relative to the detaching tool body.

In the electronic component detaching tool according to the present invention, the pair of arms are preferably each supported in a swingable manner on the detaching tool body via a spindle.

In the electronic component detaching tool according to the present invention, the detaching tool body preferably includes a handle to be held by hand by a user.

According to the present invention, by operating the pair of levers of the socket using the pair of arms, it is possible to release engagement of the engaging portions from the electronic component, and retain the electronic component from which the engaging portions have been disengaged with the retainers. As a result, an operation for disengaging the engaging portions from the electronic component and an operation for retaining the electronic component can be performed using one tool. This can achieve an improvement in the operational efficiency of a task for detaching the electronic component from the socket.

### BRIEF DESCRIPTION OF THE DRAWINGS

FIG. 1 is a perspective view of an electronic component detaching tool according to an embodiment of the present invention.

FIG. 2 is an exploded perspective view of the electronic component detaching tool according to the embodiment of the present invention.

FIG. 3 is a perspective view illustrating a board, sockets, memory modules, and a cooling device assembled together according to the embodiment of the present invention.

FIG. 4 is an exploded perspective view of the board, the sockets, the memory modules, and the cooling device according to the embodiment of the present invention.

FIG. 5 is a diagram for explaining a method for detaching a memory module from a socket according to the embodiment of the present invention.

FIG. 6 is a diagram for explaining the method for detaching a memory module from a socket according to the embodiment of the present invention.

FIG. 7 is a diagram for explaining the method for detaching a memory module from a socket according to the embodiment of the present invention.

FIG. 8 is a diagram for explaining the method for detaching a memory module from a socket according to the embodiment of the present invention.

### DETAILED DESCRIPTION OF THE EXAMPLE EMBODIMENTS

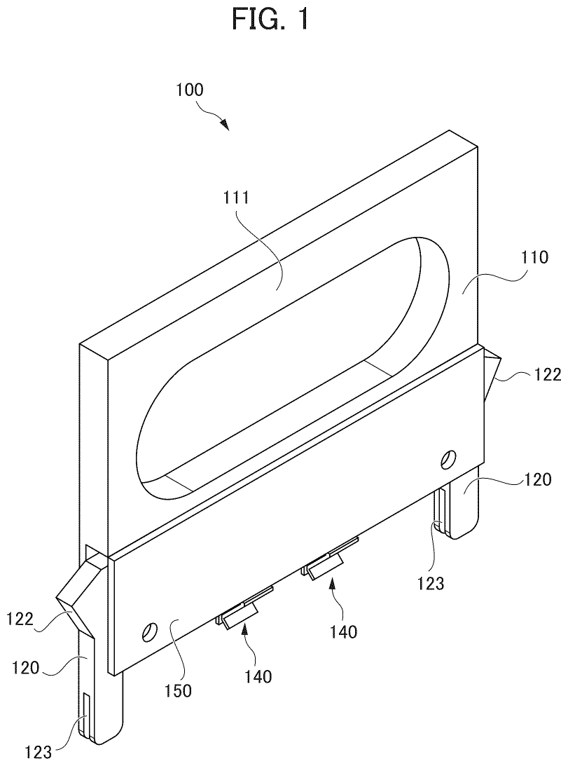

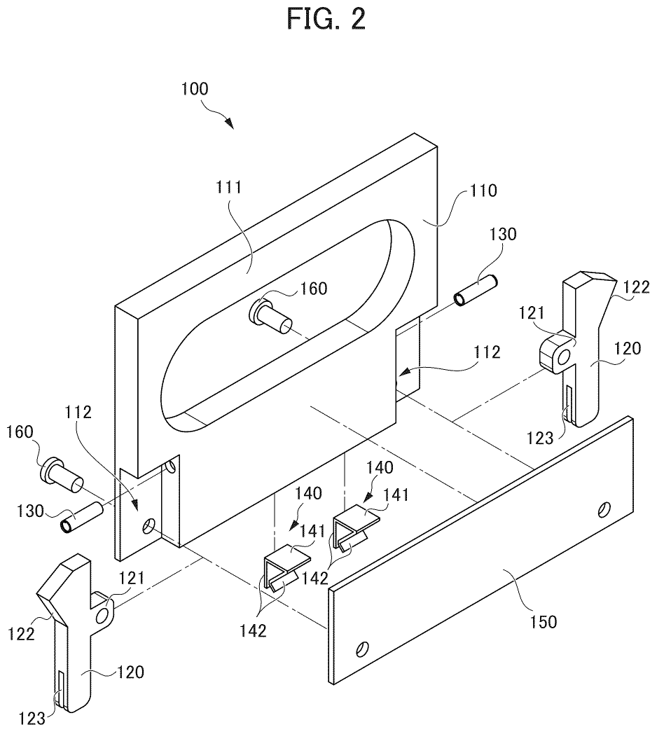

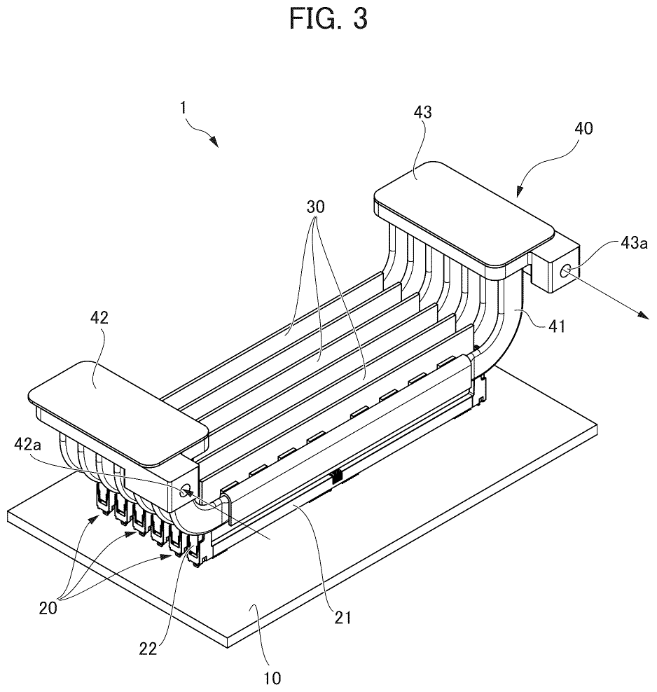

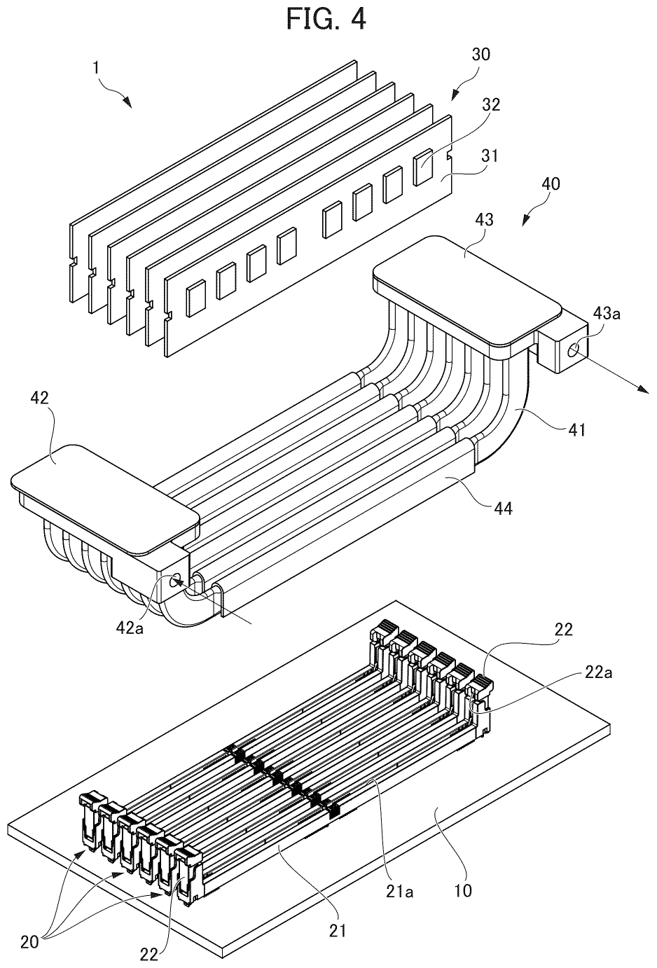

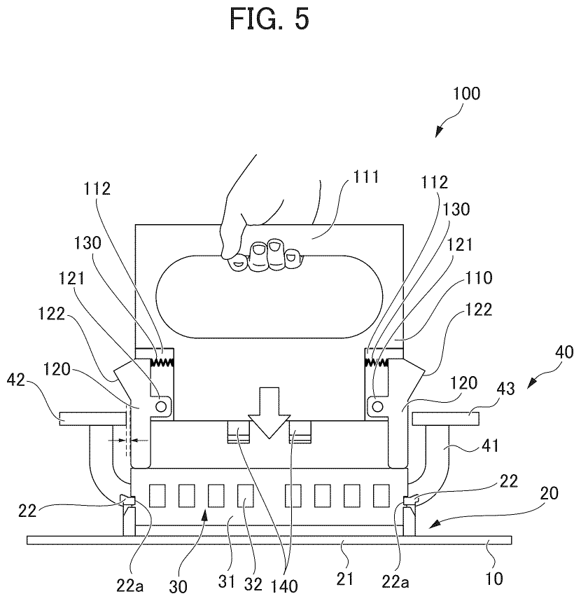

FIGS. 1 to 8 illustrate an embodiment of the present invention. FIG. 1 is a perspective view of an electronic component detaching tool, FIG. 2 is an exploded perspective view of the electronic component detaching tool, FIG. 3 is a perspective view illustrating a board, sockets, memory modules, and a cooling device assembled together, FIG. 4 is an exploded perspective view of the board, the sockets, the memory modules, and the cooling device, and FIGS. 5 to 8 are diagrams for explaining a method for detaching a memory module from a socket.

An electronic component detaching tool 100 of the present invention is used to maintain and manage a server device 1 for offering data and services to another terminal device via the Internet, for example.

As illustrated in FIGS. 3 and 4, the server device 1 includes a board 10 configured as a plate-shaped member which is made of an insulator and on which interconnects being conductors are routed, a plurality of sockets 20 arranged on the board 10, a plurality of memory modules 30 configured as a plurality of plate-shaped electronic components to be attached to the plurality of corresponding sockets 20, and a cooling device 40 configured to remove heat released from the plurality of memory modules 30.

The plurality of sockets 20 each include a socket body 21 having formed therein a groove 21a in which one end portion of the corresponding memory module 30 is inserted, and a pair of levers 22 that are operable to detach the memory module 30 inserted in the groove 21a from the socket body 21. The plurality of sockets 20 are arranged on the board 10 such that their longitudinal directions are parallel to one another.

The socket body 21 is in the form of a quadrangular prism extending along an upper surface of the board 10, and has the groove 21a formed therein that opens upward on its upper surface. A conductor (not shown) to be connected to one of the interconnects routed on the board 10 is located inside the groove 21a so that the memory module 30 inserted in the groove 21a is electrically connected to the interconnect on the board 10 through the socket body 21.

The pair of levers 22 are provided near end portions, respectively, of the socket body 21 in the extending direction of the groove 21a. The pair of levers 22 each have a lower end portion supported to freely swing by the corresponding end portion of the socket body 21 in the extending direction thereof. At an upper end portion of each of the pair of levers 22, an engaging portion 22a that is engageable with the memory module 30 inserted in the groove 21a is formed on a surface located a central portion side of the socket body 21 in the extending direction of the socket body 21. The pair of levers 22 allow the engaging portions 22a to engage with the memory module 30 inserted in the groove 21a, thereby fixing the memory module 30 in a state inserted in the groove 21a. While the engaging portions 22a engage with the memory module 30 inserted in the groove 21a, the pair of levers 22 are swung outward along the extending direction of the socket body 21 to release engagement of the engaging portions 22a from the memory module 30 inserted in the groove 21a and to move the memory module 30 inserted in the groove 21a upward.

The memory module 30 is, for example, a dual inline memory module (DIMM), and includes a board 31 having terminals and on which a plurality of memory units 32 are arranged. The engaging portions 22a of the pair of levers 22 engage with intermediate portions in the lateral direction of both longitudinal end portions of the board 31 constituting the memory module 30.

The cooling device 40 includes a plurality of cooling water flow pipes 41, an inlet manifold 42, an outlet manifold 43, and a plurality of thermally conductive sheets 44. The cooling water flow pipes 41 are attached to the sockets 20, respectively, so as to be arranged near both outer ends of a set of the memory modules 30 arranged on the board 10 and between adjacent memory modules 30. The inlet manifold 42 is connected to end portions of the cooling water flow pipes 41 near an inlet for cooling water. The outlet manifold 43 is connected to end portions of the cooling water flow pipes 41 near an outlet for cooling water. The thermally conductive sheets 44 are each configured to conduct heat between the corresponding cooling water flow pipe 41 and the memory units 32 arranged on the memory module 30 adjacent to the cooling water flow pipe 41.

The cooling water flow pipes 41 are flat pipe-shaped members, extend along an upper surface of the board to both outer ends of the set of the memory modules 30 arranged side-by-side and between the adjacent ones of the memory modules 30, and are bent upward near both longitudinal ends of the memory modules 30.

The inlet manifold 42 and the outlet manifold 43 are hollow members extending in the direction in which the cooling water flow pipes 41 are arranged side-by-side, and each have a lower surface to which corresponding end portions of the cooling water flow pipes 41 are connected. The inlet manifold 42 has a cooling water inlet 42a that allows cooling water to flow thereinto. The cooling water that has flowed from the cooling water inlet 42a into the inlet manifold 42 branches to flow through the plurality of cooling water flow pipes 41. The outlet manifold 43 has a cooling water outlet 43a that allows cooling water to flow out thereof. The cooling water that has flowed through the cooling water flow pipes 41 flows into the outlet manifold 43 to merge and flow out from the cooling water outlet 43a.

Here, the inlet manifold 42 and the outlet manifold 43 constituting the cooling device 40 are connected to both end portions of the cooling water flow pipes 41 which are bent upward. Thus, these manifolds are spaced apart from the upper surface of the board 10. One of the levers 22 of each socket 20 is located between the upper surface of the board 10 and the inlet manifold 42, and the other lever 22 of the socket 20 is located between the upper surface of the board 10 and the outlet manifold 43. In other words, the inlet manifold 42 and the outlet manifold 43 are located in the space above the pairs of levers 22 of the sockets 20. The inlet manifold 42 and the outlet manifold 43 are arranged outside in the longitudinal direction of the memory modules 30 attached to the corresponding sockets 20 of the memory modules 30 as viewed from above. In other words, a space above the memory modules 30 attached to the sockets 20 is open upward without being blocked by the inlet manifold 42 and the outlet manifold 43.

As illustrated in FIGS. 1 and 2, the electronic component detaching tool 100 according to this embodiment includes a detaching tool body 110, a pair of arms 120, a pair of posture retaining members 130, a pair of retainers 140, and a cover 150. The pair of arms 120 are configured to operate the pair of levers 22 of the corresponding socket 20. The pair of posture retaining members 130 are configured to retain the postures of the pair of arms 120 relative to the detaching tool body 110. The pair of retainers 140 are configured to retain the corresponding memory module 30. The cover 150 is configured to cover one of surfaces of a lower end portion of the detaching tool body 110.

The detaching tool body 110 is a rectangular plate-shaped member. The dimension of the detaching tool body 110 in the vertical direction is greater than at least the distance from the upper end of the memory module 30 attached to the socket 20 until the upper ends of the inlet manifold 42 and the outlet manifold 43, and the dimension of the detaching tool body 110 in the width direction thereof is substantially equal to the longitudinal size of the memory module 30. An upper end portion of the detaching tool body 110 has a long hole that extends in the width direction of the upper end portion and passes through the detaching tool body 110 in the thickness direction. Thus, a handle 111 that a user using the electronic component detaching tool 100 holds by hand is formed at the upper end portion. Both end portions in the width direction of the lower end portion of the detaching tool body 110 are partially cut away near one surface thereof, thereby forming housing portions 112 respectively configured to house a portion of a corresponding one of the pair of arms 120 and a corresponding one of the pair of posture retaining members 130.

The upper end portions of the pair of arms 120 are respectively located in the housing portions 112 of the detaching tool body 110, and lower end portions thereof protrude beyond the lower end of the detaching tool body 110. Substantially central portions of the pair of arms 120 in the vertical direction each have a supporting portion 121 that overhangs toward a central portion in the width direction of the detaching tool body 110 and that is supported on the detaching tool body 110 via a spindle 160 so as to be swingable in the width direction. The upper end portions of the pair of arms 120 each have an abutting portion 122 that overhangs toward the outside in the width direction of the detaching tool body 110 and that, when the electronic component detaching tool 100 is moved toward the memory module 30 attached to the socket 20, abuts against the inlet manifold 42 or the outlet manifold 43 serving as another member provided on the board. The amount by which each abutting portion 122 overhangs increases gradually from the central portion in the vertical direction of the corresponding one of the pair of arms 120 toward the upper end thereof. The lower end portions of the pair of arms 120 each have a cutout 123 to which the memory module 30 can enter when the electronic component detaching tool 100 is to be moved toward the memory module 30 attached to the socket 20.

The pair of posture retaining members 130 are configured as coil springs. Each posture retaining member 130 is positioned to have one end that abuts against the upper end portion of the corresponding arm 120 and another end that abuts a wall surface of the corresponding housing portion 112. The posture retaining member 130 retains the posture of the corresponding arm 120 relative to the detaching tool body 110 such that the extending direction of the arm 120 is parallel to the extending direction of both side surfaces in the width direction of the detaching tool body 110.

The pair of retainers 140 are each formed by bending a plate-shaped member having elasticity. Each retainer 140 includes a flat plate-shaped base 141 and a pair of clamping pieces 142 that overhang from ends of the base 141 in one direction while opposing each other. The spacing between the pair of clamping pieces 142 is less at their central portions between their basal ends and distal ends than the thickness of the board 31 of the memory module 30, and increases gradually from the central portions toward the basal ends and toward the distal ends. When the gap between the pair of clamping pieces 142 of the retainer 140 is moved toward the corresponding end of the memory module 30, and as a result, the pair of clamping pieces 142 abuts against the end of the memory module 30, the spacing between the pair of clamping pieces 142 is widened, and the memory module 30 is clamped between the pair of clamping pieces 142.

The cover 150 is configured as a rectangular plate-shaped member, and supports an end portion of each of the spindles 160 while being attached to one surface of the lower end portion of the detaching tool body 110.

A method for detaching the memory module 30 attached to the socket 20 on the board 10 from the socket 20 using the electronic component detaching tool 100 configured as described above will be described with reference to FIGS. 5 to 8.

First, as illustrated in FIG. 5, a lower end portion of the electronic component detaching tool 100 is inserted into the gap between the inlet manifold 42 and the outlet manifold 43, and is positioned over the memory module 30.

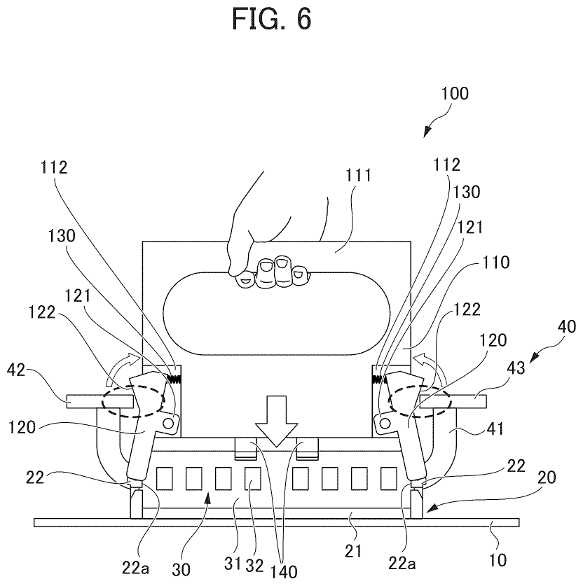

Next, both side portions in the longitudinal direction of the memory module 30 enter the corresponding cutouts 123 of the pair of arms 120 allowing the electronic component detaching tool 100 to move downward. Thus, the lower end portion of one of the arms 120 contacts the upper end portion of a corresponding one of the levers 22 of the socket 20, and the abutting portion 122 of the arm 120 abuts against the inlet manifold 42. The lower end portion of the other arm 120 contacts the upper end portion of the other lever 22 of the socket 20, and the abutting portion 122 of the other arm 120 abuts against the outlet manifold 43. In other words, each of the pair of arms 120 swings in a direction in which its lower end portion moves outward in the width direction of the detaching tool body 110, against the biasing force of the corresponding posture retaining member 130, as illustrated in FIG. 6.

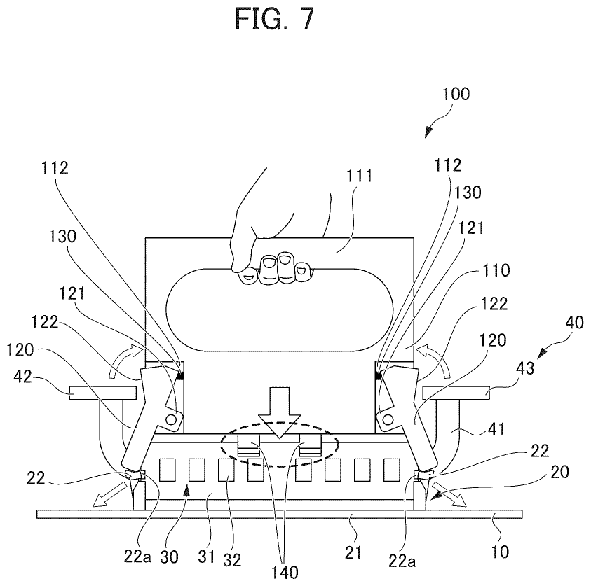

At this time, as illustrated in FIG. 7, each of the pair of levers 22 of the socket 20 is operated by the arm 120 that swings to move outward along the extending direction of the socket body 21. As a result, the engaging portions 22a are disengaged from the memory module 30 inserted in the groove 21a of the socket body 21, and the memory module 30 inserted in the groove 21a is moved upward. The memory module 30 moving upward from a state inserted in the groove 21a through operation of the pair of levers 22 is press-fitted between the pair of clamping pieces 142 of each of the pair of retainers 140, and is retained by the pair of retainers 140.

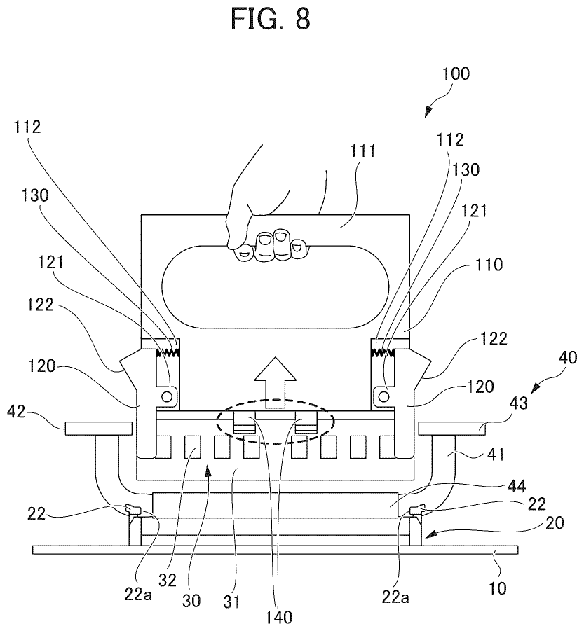

Finally, as illustrated in FIG. 8, when the electronic component detaching tool 100 is moved upward, the memory module 30 retained by the pair of retainers 140 moves upward together with the electronic component detaching tool 100, whereby the memory module 30 is detached from the socket 20.

As can be seen, the electronic component detaching tool 100 of the present embodiment is directed to an electronic component detaching tool 100 for use in detaching a plate-shaped memory module 30 attached to a socket 20 provided on a board 10. The socket 20 includes a socket body 21 having a groove 21a in which one end portion of the memory module 30 is inserted, and a pair of levers 22 respective provided on both sides of the socket body 21 in an extending direction of the groove 21a, the pair of levers 22 each having an engaging portion 22a that is engageable with the memory module 30 inserted in the groove 21a, the pair of levers 22 being moved from outside toward inside along the extending direction of the groove 21a to engage the engaging portions 22 with the memory module 30, the pair of levers 22 being moved from inside toward outside along the extending direction of the groove 21a to disengage the engaging portions 22 from the memory module 30. The electronic component detaching tool 100 includes: a detaching tool body 110; a pair of arms 120 provided to the detaching tool body 110 to respectively operate the pair of levers 22 in a state where the engaging portion 22a is engaged with the memory module 30 inserted in the groove 21a in a direction to disengage the engaging portions 22a from the memory module 30; and a retainer 140 provided to the detaching tool body 110 to retain the memory module 30 for which engagement of the engaging portions 22a has been released by the pair of arms 120.

Thus, by operating the pair of levers 22 of the socket 20 using the pair of arms 120, it is possible release engagement of the engaging portions 22a from the memory module 30, and retain the memory module 30 from which the engaging portions 22a have been disengaged with the retainers 140. As a result, an operation for disengaging the engaging portions 22a from the memory module 30 and an operation for retaining the memory module 30 can be performed using one tool. This can achieve an improvement in the operational efficiency of a task for detaching the memory module 30 from the socket 20.

The pair of arms 120 each preferably include the abutting portion 122 configured to abut against the inlet manifold 42 or the outlet manifold 43 spaced apart upward from a corresponding one of the levers 22 over the board 10, when the detaching tool body 110 is moved toward the memory module 30 inserted in the groove 21a of the socket body 21, and an action is preferably performed of operating the lever 22 in a direction to disengage the engaging portion 22a from the memory module 30 by the abutting portion 122 abutting against the inlet manifold 42 or the outlet manifold 43.

This eliminates the need for power intended only to actuate the pair of arms 120, and enables disengagement of the engaging portions 22a from the memory module 30 through an action of moving the detaching tool body 110 toward the memory module 30. This can achieve a reduction in the manufacturing cost.

The posture retaining member 130 configured to retain postures of the pair of arms 120 relative to the detaching tool body 110 is preferably provided.

This configuration allows the postures of the pair of arms 120 relative to the detaching tool body 110 to be retained irrespective of the orientation of the detaching tool body 110. Thus, the pair of levers 22 can be reliably operated by the pair of arms 120.

The pair of arms 120 are each preferably supported in a swingable manner on the detaching tool body 110 via the spindle 160.

This configuration allows the pair of arms 120 to be smoothly swung relative to the detaching tool body 110. Thus, the pair of levers 22 can be reliably operated by the pair of arms 120.

The detaching tool body 110 includes the handle 111 that a user holds by hand.

Operating the electronic component detaching tool 100 with the handle 111 held by a user thereby enables reliable operation of the electronic component detaching tool 100.

It should be noted that, although the embodiment shows the memory module 30 as the plate-shaped electronic component, the plate-shaped electronic component is not to be limited to the memory module 30 so long as being detachably attached to a socket or a slot on a board.

The embodiment shows the inlet manifold 42 and the outlet manifold 43 constituting the cooling device 40 as other members provided on the board 10. However, the other members are not to be limited to the inlet manifold 42 and the outlet manifold 43 so long as being spaced apart directly above the levers 22 of the socket 20 in a state where operation of the levers 22 from above the board 10 is difficult.

### REFERENCE SIGNS LIST

10: Board
20: Socket
21: Socket Body
21a: Groove
22: Lever
22a: Engaging Portion
30: Memory Module
42: Inlet Manifold
43: Outlet Manifold
100: Electronic Component Detaching Tool
110: Detaching Tool Body
120: Arm
122: Abutting Portion
130: Posture Retaining Member
140: Retainer
160: Spindle

What is claimed is:

1. An electronic component detaching tool for use in detaching a plate-shaped electronic component attached to a socket provided on a board,
the socket including
a socket body having a groove in which one end portion of the electronic component is inserted, and
a pair of levers respectively provided on both sides of the socket body in an extending direction of the groove, the pair of levers each having an engaging portion that is engageable with the electronic component inserted in the groove, the pair of levers being moved from outside toward inside along the extending direction of the groove to engage the engaging portions with the electronic component, and the pair of levers being moved from inside toward outside along the extending direction of the groove to disengage the engaging portions from the electronic component,
the electronic component detaching tool comprising:
a detaching tool body;
a pair of arms provided to the detaching tool body to respectively operate the pair of levers in a state where the engaging portion is engaged with the electronic component inserted in the groove in a direction to disengage the engaging portions from the electronic component; and
a retainer provided to the detaching tool body to retain the electronic component for which engagement of the engaging portions has been released by the pair of arms.

2. The electronic component detaching tool of claim 1, wherein
the pair of arms each include
an abutting portion configured to abut against one other member spaced apart upward from a corresponding one of the levers on the board, when the detaching tool body is moved toward the electronic component inserted in the groove of the socket body, and
an action of operating the lever in a direction releasing engagement of the engaging portion from the electronic component is performed by the abutting portion abutting against the other member.

3. The electronic component detaching tool of claim 1 further comprising:
a posture retaining member configured to retain postures of the pair of arms relative to the detaching tool body.

4. The electronic component detaching tool of claim 1, wherein
the pair of arms are each supported in a swingable manner on the detaching tool body via a spindle.

5. The electronic component detaching tool of claim 1, wherein
the detaching tool body includes a handle to be held by hand by a user.
